(19) United States
(12) Patent Application Publication
(10) Pub. No.: US 2004/0084298 A1
(43) Pub. Date: May 6, 2004

(54) Fabrication of nanocomposite thin films for high density magnetic recording media

(76) Inventors: Y.D. Yao, Taipei (TW); Po-Cheng Kuo, Taipei (TW); Sheng-Chi Chen, Taipei (TW); An Cheng Sun, Junghe City (TW); Chen-Chieh Chiang, Feng Shan City (TW)

Correspondence Address: BING AI, Fish & Richardson P.C., Suite 500, 4350 La Jolla Village Drive, San Diego, CA, 92122, US

(21) Appl. No.: 10/286,601

(22) Filed: Oct. 31, 2002

(51) Int. Cl. C23C 14/34

(52) U.S. Cl. 204/192.2

(57) ABSTRACT

Techniques for fabricating magnetic granular films for high-density magnetic data storage, where magnetic grains are dispersed in a non-magnetic amorphous matrix and each are surrounded by a grain-confining material which inhibits growth of grains during annealing.

### BACKGROUND

This application relates to granular films formed on substrates, and more specifically, to fabrication of magnetic granular films for data storage.

Various magnetic granular films have been developed and investigated for magnetic data storage applications. Such films may be designed to include magnetic grains with high magnetic coercivity and large remnant magnetization. The magnetic grains interact with the magnetic field from a suitable magnetic head to receive data for storage in a writing operation, or output data that is previously stored in the grains in a reading operation.

One suitable material for such magnetic granular films, for example, is FePt-based magnetic thin films. FePt grains or particles exhibit magnetic properties suitable for magnetic data storage. In particular, FePt grains may be dispersed in a nonmagnetic and amorphous SiN matrix so that FePt grains may be spatially separated or isolated from one another. This spatial separation can reduce noise caused by inter-grain magnetic coupling between adjacent FePt grains and thus enhance the performance of the such films in magnetic recording. FePt-based magnetic thin films may be designed to produce high coercivity H_{c}, relative good remnant magnetization Mᵣ, high magnetocrystalline anisotropy Kᵤ, small grain size, good corrosion resistance, and large energy products (BH)ₘₐₓ. Such FePt-based thin films may be used as attractive media for high-density magnetic recording applications.

### SUMMARY

This application includes techniques for fabricating composite granular films with isolated magnetic grains dispersed in a nonmagnetic matrix for high-density recording media. According to one embodiment, the fabrication may include the following steps. First, a suitable magnetic material, a grain-confining material, and a non-magnetic amorphous material are sputtered on a substrate to form a granular film, where grains of the magnetic material are dispersed in a amorphous matrix of the non-magnetic material. The grain-confining material, which may be a non-magnetic material, is selected so that it mainly resides at the boundary of the magnetic grains to confine the size of each grain and to achieve a desired small grain size in the finished film. Next, the granular film is annealed at an elevated annealing temperature over a selected period and then is quenched in a suitable quenching liquid to transform the magnetic grains from a soft magnetic phase into a hard magnetic phase with desired magnetic properties.

According to one aspect of the application, prior to the annealing treatment, a passivation cap layer may be formed on the granular film to protect the film from oxidation during the annealing treatment. A silicon nitride, such as SiN_{y}, or other suitable passivation materials, may be used to form this passivation cap layer.

In one implementation, the magnetic material may be FePt, the grain-confining material may be Cr, and the non-magnetic material may be a silicon nitride such as Si₃N₄. The substrate for supporting the film may be a naturally-oxidized silicon substrate or a glass substrate. The properties of the finished composite granular films by the above fabrication process are sensitive to various process parameters and thus exemplary values for the process parameters are disclosed for FePt-based films to achieve desired film properties for magnetic recording.

These and other features and associated advantages are now described in greater detail in the following drawings, the textual description, and the claims.

### BRIEF DESCRIPTION OF THE DRAWINGS

FIG. 1 shows a flowchart for processing steps in fabricating such a granular thin film for high-density magnetic storage according to one embodiment.

FIG. 2 shows one exemplary operational flow in fabricating a FePt-based granular film for magnetic recording according to the technique shown in FIG. 1.

FIG. 3 illustrates the variation of average grain size with SiN_{y} volume fraction of the various annealed (Fe₄₅Pt₄₅Cr₁₀)_{100-δ}-(SiN_{y})_{δ} film, where the annealing temperatures are 500° C., 550° C., 600° C., and 700° C., respectively.

FIG. 4 illustrates the relations between δM and applied field Ha of various annealed (Fe₄₅Pt₄₅Cr₁₀)_{100-δ}-(SiN_{y})_{δ} films with different SiN_{y} volume fractions.

FIG. 5 illustrates the variation of average grain size with Cr content of the annealed (Fe_{50-x/2}Pt_{50-x/2}Crₓ)₈₅-(SiN_{y}) ₁₅ films, where the film thickness is about 10 nm and annealing time is about 30 minutes.

FIG. 6 illustrates the relations between δM and Ha of various (Fe_{50-x/2}Pt_{50-x/2}Crₓ)₈₅-(SiN_{y})₁₅ films with different Cr contents.

FIGS. 7A and 7B shows the relation between in-plane squareness S_{//} and Cr content of the annealed (Fe_{50-x/2}Pt_{50-x/2}Crₓ)₈₅(SiN_{y})₁₅ film, and the relation between S_{//} and SiN_{y} volume fraction of the annealed (Fe₄₅Pt₄₅Cr₁₀)_{100-δ}-(SiN_{y})_{δ} film, respectively.

FIGS. 8A and 8B respectively show variations of Hc_{//} and Ms with Cr content of the annealed (Fe_{50-x/2}Pt_{50-x/2}Crₓ)₈₅-(SiN_{y})₁₅ film, and variations of Hc_{//} and Ms with SiN_{y} volume fraction of the annealed (Fe₄₅Pt₄₅Cr₁₀)_{100-δ}-(SiN_{y})_{δ} film. The film thickness is 10 nm.

FIG. 9 is the M-H loop of annealed (Fe₄₅Pt₄₅Cr₁₀)₈₅-(SiN_{y})₁₅ thin film which is of 10 nm in thickness and was annealed at 600° C. for about 30 minutes.

### DETAILED DESCRIPTION

The fabrication techniques of this application are in part based on the recognition that it is desirable to reduce both the inter-grain interactions of neighboring magnetic grains and the dimension of each magnetic grain in granular films to achieve high storage density in magnetic recording. The intergrain interactions of neighboring magnetic grains may be reduced by interspersing the magnetic grains in an amorphous nonmagnetic matrix such as a silicon nitride to spatially separate the magnetic grains. This spatial separation can reduce the noise caused by inter-grain interactions, such as inter-grain magnetostatic and exchange interactions of neighboring magnetic grains.

In addition to the physical separation of grains for reducing noise, the physical dimension of each magnetic grain may also limit the density of the data storage. Hence, another aspect of this application is to mix a grain-confining material in the granular film to be present on the boundaries of each magnetic grain to inhibit the growth of the magnetic grain. This reduced grain dimension allows for an increase in the density of magnetic grains in a given area and thus increases the storage density.

In another aspect, the crystal anisotropy constant of the magnetic grains should be large to achieve a large in-plane magnetic coercivity for magnetic recording. As described below, the relative amounts of different materials, including the amount of the grain-confining material, should be properly selected to achieve the desired crystal anisotropy constant.

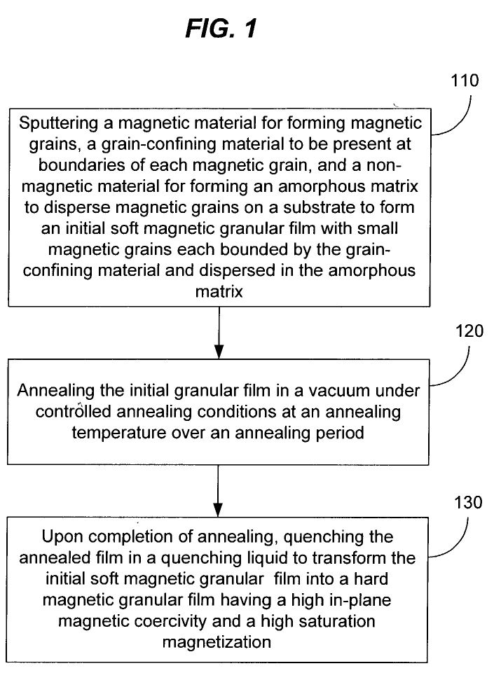

FIG. 1 shows a flowchart for processing steps in fabricating such a granular thin film for high-density magnetic storage according to one embodiment. A suitable substrate for supporting the granular film is selected and prepared for film deposition. Silicon substrates or glass substrates, among others, may be used. At step 110, a magnetic material for forming magnetic grains, a grain-confining material to be present at boundaries of each magnetic grain, and a non-magnetic material for forming an amorphous matrix to disperse magnetic grains are sputtered on a substrate to form an initial soft magnetic granular film with small magnetic grains each bounded by the grain-confining material and dispersed in the amorphous matrix.

As further illustrated in the examples below, the ratios of the three materials for the granular film should be properly selected to achieve the desired overall film properties for magnetic recording. For example, the grain dimension can be reduced when the content of the grain-confining material increases in the film. However, as the grain-confining material increases in the film, it may diffuse from the boundary of each grain to the grain surface to adversely reduce the crystal anisotropy constant of the magnetic grains. Also, if the grain-confining material is non-magnetic like Cr in FePt-based films, an increased content of the grain-confining material can also adversely reduce the saturation magnetization Ms of the finished granular film. Such adverse effects weigh against an increase in the content of the grain-confining material. Hence, an optimal or near optimal value for the grain-confining material should be selected to balance the competing effects.

With respect to the non-magnetic material, the grain dimension may decrease with an increase in the volume fraction of the non-magnetic material. Hence, it is desirable to increase the volume fraction of the non-magnetic to decrease the grain dimension.

However, on the other hand, as demonstrated in FePt-based films, the non-magnetic material matrix in the granular film provides an environment in which the magnetic grains are dispersed and are spatially separated to beneficially reduce the noise caused by inter-gain coupling. Hence, an increase in the volume fraction of the non-magnetic material in the film can beneficially reduce the strength of the inter-grain coupling. In addition, to an certain extent, an increase in the volume fraction of the non-magnetic material matrix in the granular film can beneficially increase the saturation magnetization of the finished granular film. In this regard, the saturation magnetization reaches a maximum value at an optimal volume fraction and decreases as when the volume faction increases beyond the optimal value.

Furthermore, the non-magnetic material matrix in the granular film can also have a protective effect to beneficially reduce an adverse reaction between magnetic grains and the underlying substrate under a high-temperature condition such as during the annealing process, where one undesirable effect of the reaction is a reduction in the saturation magnetization. Since the non-magnetic material matrix can also dilute the saturation magnetization of the finished granular film, its volume fraction in the film has an optimal value below which an increase in the volume faction can increase the saturation magnetization and above which an increase in the volume faction can decrease the saturation magnetization.

The above various effects associated with the ratios of the three materials for the granular film suggest that there competing effects in selecting the quantity of each of the three materials. All the effects on the properties of the final granular film should be considered in selecting a desired ratio. In addition, various processing parameters can also impact the film properties. Several examples are given below to illustrate this aspect in implementing the fabrication method shown in FIG. 1. It is discovered that one preferred range for the material ratios for Fe:Pt:Cr in the FePt film is between about 45:54:1 to about 41:34:25, where the ratio of 45:45:10 is preferred. The volume fraction of FePtCr:SiN is in the range from about 90:10 to about 50:50 where the ratio of about 85:15 is preferred.

Referring back to the step 110 in FIG. 1, the sputtering may be performed in a vacuum chamber filled with Ar gas. Electrodes are provided in the chamber where an electrical field is applied to ionize the Ar to produce Ar plasma. Charged Ar ions in the Ar plasma are accelerated to hit the cathode surface where the target materials, i.e., the magnetic material, the grain-confining material, and the non-magnetic material, are located. This bombardment on the target materials by the Ar ions causes the targeted materials to be sputtered on the substrate located near the cathode surface to form the granular film. The substrate temperature and the Ar pressure are two important parameters for controlling the sputtering process. It is discovered that the Ar pressure may be in the range from about 0.3 mTorr to about 20 mTorr, where a pressure of about 7 mTorr for the Ar gas is preferred. The substrate temperature may be set at a relatively low temperature below about 45° C., preferably around 25° C., to produce granular films with desired properties.

The sputtering system suitable for the fabrication may be a magnetron sputtering system where a magnetic field is generated at the cathode to enhancing trapping of electrons. Such a system can achieve a high deposition rate. In implementation, such magnetron sputtering system may apply a DC electric field across the electrodes to create the plasma, or alternatively, apply an RF electric field across the electrodes to create the plasma.

The magnetic grains in the granular film formed from sputtering process are generally in a soft magnetic phase. Additional processing operations are performed to transform the magnetic grains into the hard magnetic phase for data storage. In implementations described in this application, annealing shown as step 120 and quenching shown as step 130 are used to achieve this transformation. Annealing is generally performed at an elevated high temperature. To prevent any undesired oxidation in the granular film in the soft magnetic phase, a passivation layer may be deposited on the soft granular film before the annealing is performed. Various passivation materials may be used here, including a silicon nitride (e.g., SiN_{y}).

At step 120, the granular film is annealed in a vacuum at an annealing temperature over a suitable annealing period. In presence of the non-magnetic material matrix and especially the grain-confining material present at boundaries of the grains during the annealing, the growth of the magnetic grains is inhibited. It is discovered that the vacuum may be below about 10⁻⁶ Torr during annealing, the annealing temperature between about 400° C. and about 800° C. where a temperature at about 600° C. is preferred, and the annealing period between about 5 to 90 minutes where a period of about 30 minutes is preferred.

Upon completion of the annealing, at step 130 in FIG. 1, the annealed granular film is then quickly cooled down in a quenching liquid to complete the transformation of the magnetic grains from the soft phase to the hard phase. The quenching liquid may be at a temperature below about 5° C. In one implementation, for example, a mixture of ice and water at about 0° C. may be used as the quenching liquid.

The following describes in detail examples for fabrication of FePtCr-based granular films based on the above method shown in FIG. 1. The substrate may be Si substrates such as a naturally oxidized Si substrate or a glass substrate. The magnetic material for forming the magnetic grains is FePt. The grain-confining material is Cr, and the non-magnetic material for the amorphous matrix is a silicon nitride.

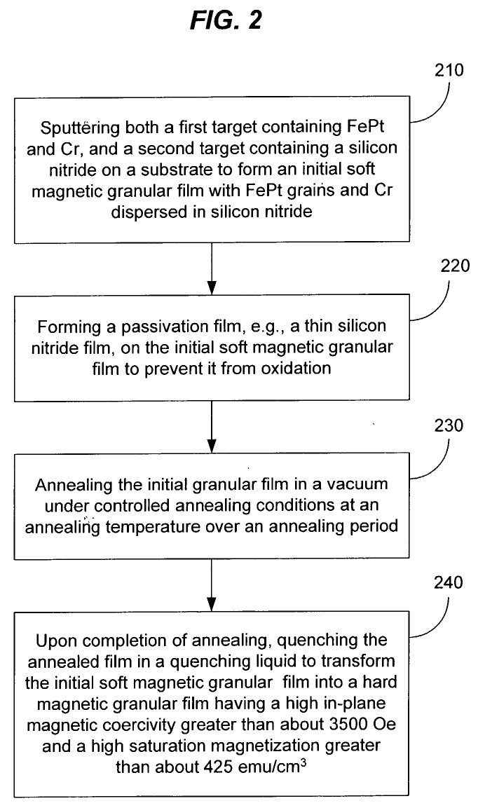

FIG. 2 shows one exemplary operational flow in fabricating a FePt-based granular film for magnetic recording, where steps 210, 220, 230, and 240 represent the sputtering process, the formation of the passivation layer, the annealing process, and the quenching process, respectively. The FePtCr target having FePt and Cr may an FePtCr alloy target, or FePtCr composite targets where each composite target includes an FePt disk overlaid with Cr chips. The method in FIG. 2 allows for fabrication of high coercivity FePtCr-SiN granular nanocomposite thin films for magnetic recording media.

In one implementation, (Fe_{50-x/2}Pt_{50-x/2}Crₓ)_{100-δ}-(SiN_{y})_{δ} nanocomposite thin films with x=0-30 at %, and δ=0-30 vol. % were fabricated on glass such as Corning 1737F glass or natural oxidized silicon wafer substrate such as Si(100). The sputtering was achieved by using DC and RF magnetron for co-sputtering of FePtCr, and Si₃N₄ targets at ambient temperature. The as-deposited film has soft magnetic properties and granular structure with soft magnetic γ-FePt particles dispersed in amorphous SiN matrix. The as-deposited film generally cannot be used as magnetic recording medium due to its low coercivity. After annealing at controlled conditions for a desirable temperature and time period in vacuum, the film also maintains its granular structure but the magnetic soft γ-FePt phase is transformed into magnetic hard γ₁-FePt phase. This transformed film has a high coercivity and a small grain size. It can be used for extremely high density magnetic recording medium.

At step 240, the sputtering process allows for the high coercivity FePt particles to be dispersed in non-magnetically amorphous silicon nitride matrix to reduce the grain size of magnetic recording thin film, resulting an increase in the recording density of the film. In absence of Cr as the grain-confining material, however, the FePt magnetic particle in the film is generally sufficiently small for certain high-density recording. For example, FePt particles have been found to be about 30 nm in FePt-Si₃N₄ film which can limit the recording density of the film. Hence, the size of magnetic particles must be decreased in order to increase the recording density. This is accomplished by adding Cr to the FePt alloy film to inhibit the grain growth of FePt owing to the precipitation of Cr at the grain boundary of FePt. The particle size of magnetic particles can be decreased to below 10 nm by the addition of Cr.

During the sputtering, the substrate was rotated in order to obtain a uniform composition of the film. At step 220, a thin cap layer of SiN_{y} is covered on the magnetic film as a passivation layer to protect the film from oxidation during the subsequent annealing. After deposition, the film was annealed in vacuum at various temperatures then quenched in ice-water after annealing (Steps 230 and 240). The magnetic easy axes of these films are parallel to film plane. The annealed FePtCr-SiN thin films show a in-plane coercivity Hc_{//}>. 3500 Oe, saturation magnetization Ms>425 emu/cm³, and the in-plane squareness S_{//}, i.e., the ratio of Mᵣ/Mₛ, is about 0.75. These films may be used for extremely high-density magnetic recording media.

Table 1 lists the sputtering parameters for the preparation of FePtCr-SiN thin films. The base pressure of the sputter chamber was approximately 3×10⁻⁷ Torr and films were deposited under an argon pressure P_{Ar} between 0.3 and 20 mTorr in order to get good magnetic properties. P_{Ar}=7 mTorr is preferred. The sputtering guns were charged with the following power densities: the applied DC power source was set at 2 W/cm² for FePtCr target and RF power source for Si₃N₄ target was varied from 1.5 to 12 W/cm². The deposition rate of FePtCr is about 0.3 nm/s. The substrate temperature was less than 45° C., for example, about 25° C. The as-deposited film was annealed in vacuum at temperature between 400° C. and 800° C. for 5-90 minutes then quenched in ice water. The temperature of quenching liquid is less than 5° C., for example, about 0° C.

TABLE 1

| Substrate temperature (Ts) | Ambient temperature |
|---|---|
| RF power density | 1.5˜12 W/cm² for Si₃N₄ target |
| DC power density | 2 W/cm² for FePtCr target |
| Base vacuum | 3 × 10⁻⁷ Torr |
| Distance between substrate | 6 cm |
| and target | |
| Argon pressure | 0.3˜20 mTorr |
| Argon flow rate | 50 ml/min |

More examples are set forth below to illustrate various features of the techniques shown in FIGS. 1 and 2. The film microstructure was observed by transmission electron microscopy (TEM) and the average grain size of the film was calculated from the TEM bright field image. Magnetic properties were measured at room temperature by a vibrating sample magnetometer (VSM) and a superconducting quantum interference device (SQUID), with maximum applied fields of 13 and 50 kOe, respectively. Composition and homogeneity of the films were determined by energy disperse spectrum (EDS). Thickness of the film was measured by an atomic force microscope (AFM).

### EXAMPLE 1

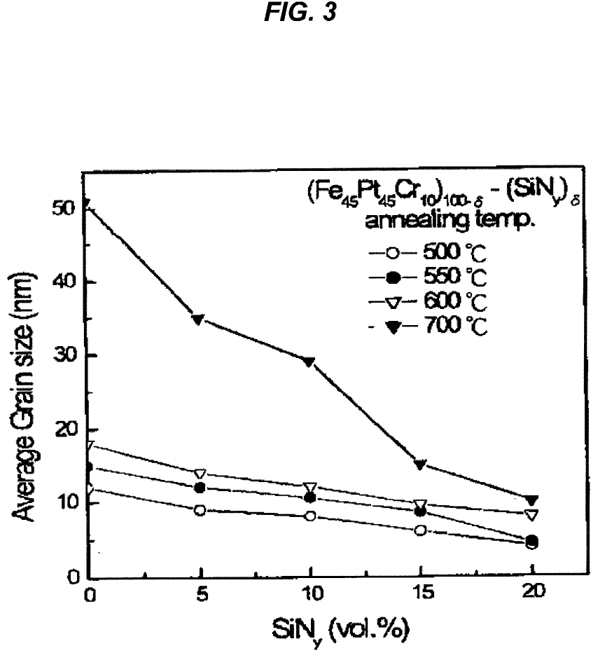

The initial substrate temperature was at room temperature. The substrate rotated at a speed of 75 rpm. After the sputtering chamber was evaluated to 3×10⁻⁷ Torr, Ar gas was introduced into the chamber. The Ar pressure was maintained at 7 mTorr during the entire sputtering period. The sputtering conditions for producing FePtCr-SiN thin films were shown in Table 1. FIG. 3. shows the variation of average grain size with SiN_{y} volume fraction of the various annealed (Fe₄₅Pt₄₅Cr₁₀)_{100-δ}- (SiN_{y})_{δ} films. Annealing temperatures are at 500° C., 550° C., 600° C., and 700° C., respectively. The Cr content is fixed at 10 at. %. The film thickness is 10 nm and the annealing time is about 30 minutes. It indicates that the grain size of FePtCr thin film increases with increasing annealing temperature but decreases with increasing the volume fraction of SiN_{y}. As annealing at 600° C., the average grain size for the annealed (Fe₄₅Pt₄₅Cr₁₀) alloy film (SiN_{y}=0 vol. %) is about 18 nm, but it can decrease to about 9.5 nm as SiN_{y} volume fraction is increased to 15 vol. %. TEM bright field images reveal that average grain size of the annealed Fe₄₅Pt₄₅Cr₁₀ alloy film is about 18 nm and it is about 8 nm for (Fe₄₅Pt₄₅Cr₁₀)₈₀-(SiN_{y})₂₀ nano-composited film. FIG. 3. and the associated TEM images also suggest that the interparticles distance is increased and the magnetic particles become smaller as SiN_{y} volume fraction of the film is increased.

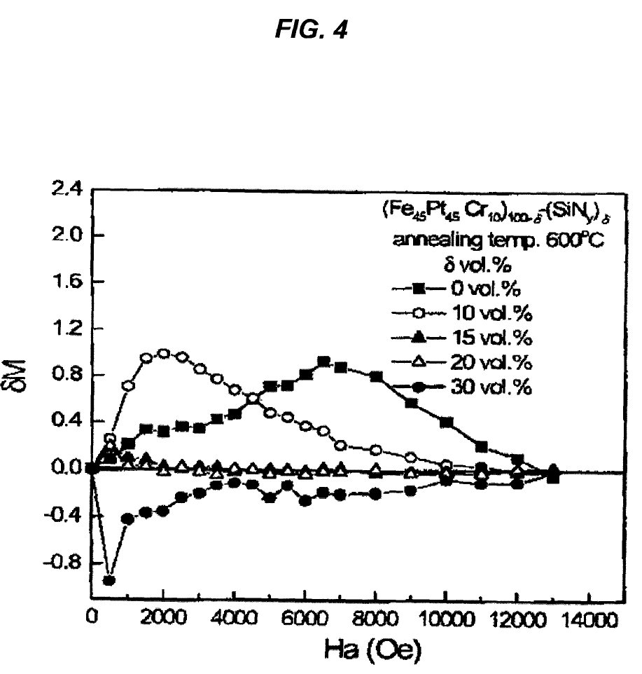

FIG. 4 shows the relations between δM and Ha of various annealed (Fe₄₅Pt₄₅Cr₁₀)_{100-δ}-(SiN_{y})_{δ} films with different SiN_{y} volume fractions. The Cr content is fixed at 10 at. % . Positive δM shows strong interactions among magnetic particles and the type of particle interactions is exchange coupling. Negative δM shows weak magnetic particle interactions and the type of particle interactions is magnetic dipole interaction. In practice, medium noise is expected as low as possible, therefore negative δM of the magnetic film is preferable for magnetic recording media application. It shows that δM value of the (Fe₄₅Pt₄₅Cr₁₀) alloy film ( SiN_{y}=0 vol. % ) is positive as shown in FIG. 4, the interaction of magnetic grains in this film is exchange coupling. The value of δM decreases to about zero as SiN_{y} volume fraction of the film increases to about 20 vol. % and becomes negative as SiN_{y} volume fraction increases further. As SiN_{y}volume fraction of the film reaches 30 vol. %, δM becomes negative and the type of interparticles interactions is dipole interaction. Increasing SiN_{y} volume fraction of the magnetic film can decrease the strength of interparticles interactions, this is because higher SiN_{y} volume fraction expands the distance among magnetic particles.

### EXAMPLE 2

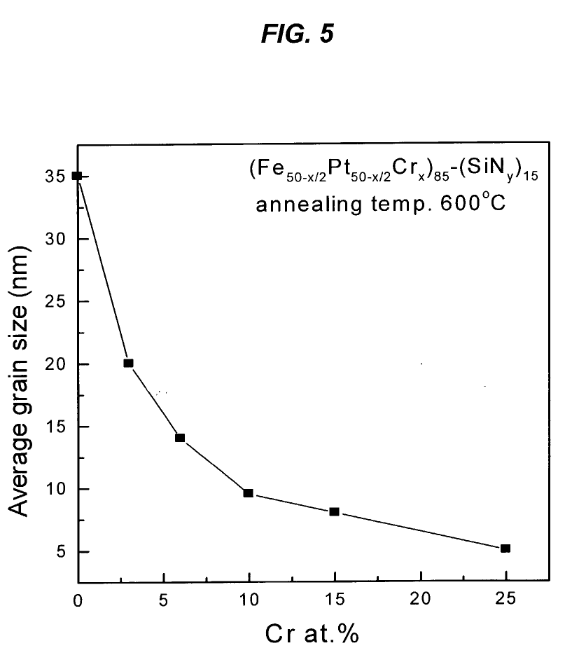

The sputtering conditions were the same as those in Example 1. FIG. 5 shows the variation of average grain size with Cr content of the annealed (Fe_{50-x/2}Pt_{50-x/2}Crₓ)₈₅-(SiN_{y})₁₅ film. The volume fraction for SiN_{y} in the film is fixed at 15 vol. %. It is evident in FIG. 5 that average grain size of the film decreases as Cr content of the film increases. For the annealed (Fe₅₀Pt₅₀)₈₅-(SiN_{y})₁₅ film (Cr=0 at. %), the average grain size is about 35 nm, but it decreases to about 9.5 nm as Cr content increases to 10 at. %. The associated TEM bright field images were obtained for the annealed (Fe₅₀Pt₅₀)₈₅-(SiN_{y})₁₅ film (Cr =0 at. % ) and (Fe_{42.5}Pt_{42.5}Cr₁₅)₈₅-(SiN_{y})₁₅ film, respectively, where the film thickness is 10 nm and annealing time is 30 min. Average grain size of (Fe₅₀Pt₅₀)₈₅-(SiN_{y})₁₅ film (Cr=0 at. %) is about 35 nm and it is about 8 nm for (Fe_{42.5}Pt_{42.5}Cr₁₅)₈₅-(SiN_{y})₁₅ film. FIG. 4. and the associated TEM images suggest that, the magnetic particles become smaller and the interparticle distance increases as Cr content of the film is increased.

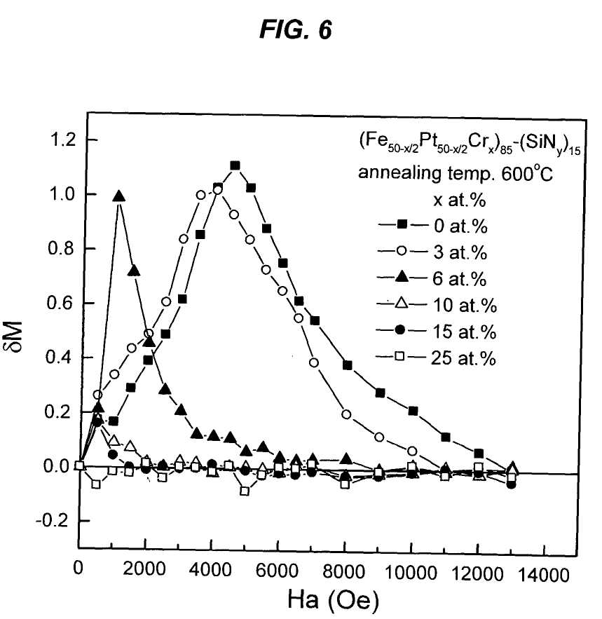

FIG. 6. shows the relations between δM and applied field Ha of the various (Fe_{50-x/2}Pt_{50-x/2}Crₓ)₈₅-(SiN_{y})₁₅ films with different Cr contents. The volume fraction of SiN_{y} in the film is fixed at 15 vol. %. The film thickness is 10 nm and annealing time is 30 min. The δM value of the (Fe₅₀Pt₅₀)₈₅-(SiN_{y})₁₅ film (Cr=0 at. %) is positive under applied field, so the type of magnetic particle interactions in this film is exchange coupling. As Cr content increases, the size of magnetic particles in the (Fe_{50-x/2}Pt_{50-x/2}Crₓ)₈₅-(SiN_{y})₁₅ film is decreased and the distance between magnetic particles becomes larger, and the strength of magnetic particles interactions is reduced. For this reason, δM of the film decreases when Cr content is increased as shown in FIG. 6. As Cr content is increased to 25 at. %, δM of the film is decreased to a small negative value and the inter-particle interactions become dipole interaction. The TEM images also confirm the δM-Ha curves of FIGS. 4 and 6, where an increases Cr or SiN_{y} content of the film under the testing conditions increases the distance among particles and reduces the strength of magnetic particle interactions.

### EXAMPLE 3

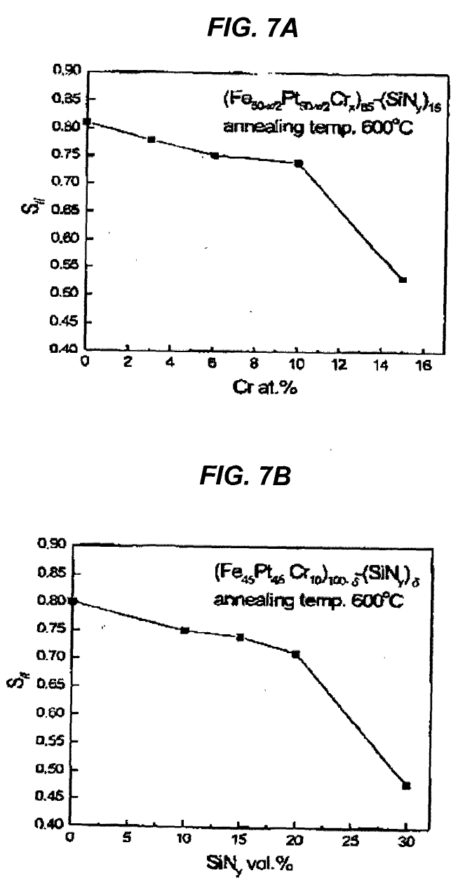

The sputtering conditions were the same as Example 1. FIG. 7A shows the relation between in-plane squareness S_{//} and Cr content of the annealed (Fe_{50-x/2}Pt_{50-x/2}Crₓ)₈₅-(SiN_{y})₁₅ film. SiN_{y} volume fraction of the film is fixed at 15 vol. %. FIG. 7B shows the variation of S_{//} with SiN_{y} volume fraction of the annealed (Fe₄₅Pt₄₅Cr₁₀)_{100-δ}-(SiN_{y})_{δ} film. The Cr content is fixed at 10 at. % and the film thickness is 10 nm, the annealing temperature is 600° C., and annealing time is 30 min. It is evident that S_{//} value of FIG. 7A drops as Cr content increases. The value of S_{//} is 0.81 when Cr=0 at. % and S_{//} is down to about 0.53 as Cr content is increased to 15 at. %. Similarly, S_{//} value of FIG. 7B goes down as SiN_{y} content increases. S_{//} is 0.8 when SiN_{y}=0 vol. % and S_{//} is down to about 0.48 as SiN_{y} volume fraction of the magnetic film is increased to 30 vol. %. These measurements suggest that the magnetic FePtCr particles become randomly oriented and isolated as Cr or SiN_{y} content of the FePtCr-SiN film is increased.

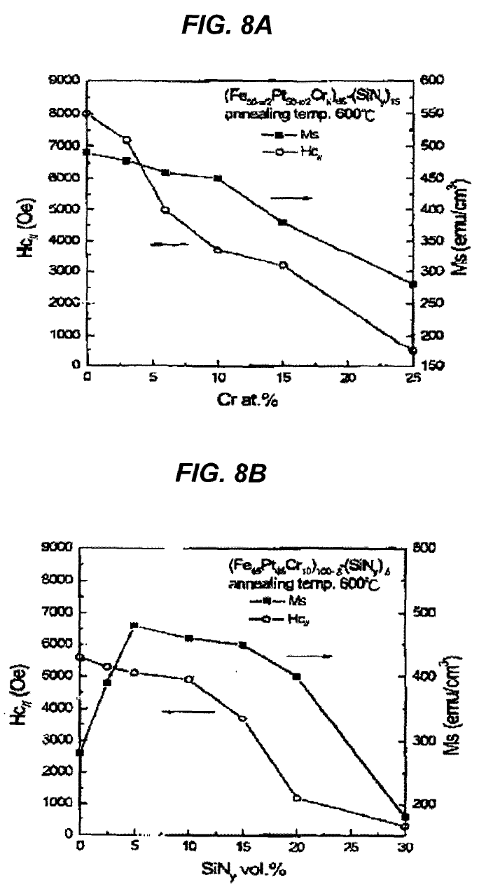

It is discovered that, an increase in either Cr or SiN_{y} content can decrease the in-plane coercivity Hc_{//} of the annealed (Fe_{50-x/2}Pt_{50-x/2}Crₓ)_{100-δ}-(SiN_{y}) film. When SiN_{y} volume fraction is fixed at 15 vol. %, Hc_{//} of the annealed (Fe_{50-x/2}Pt_{50-x/2}Crₓ)₈₅-(SiN_{y})₁₅ film is decreased as Cr content increases, as shown in FIG. 8A where the value of Hc// of the annealed (Fe₅₀Pt₅₀)₈₅-(SiN_{y})₁₅ film ( Cr=0 at. % ) is about 8000 Oe, but it decreases to about 3700 Oe as Cr content increases to 10 at. %. The films of FIGS. 8A and 8B are annealed at 600° C. for 30 min and the substrate is silicon wafer. Similarly, when Cr content is fixed at 10 at. %, Hc_{//} value of the annealed (Fe₄₅Pt₄₅Cr₁₀) film (SiN_{y}=0 vol. %) is about 5600 Oe, and it can decrease to about 350 Oe as SiN_{y} volume fraction of the film increases to 30 vol. % as shown in FIG. 8B. Increasing Cr or SiN_{y} content of the magnetic film can inhibit the magnetic grain growth during annealing and thus causes the grain size to deviate from the single domain size. In fact, some grains even become superparamagnetic particles. Moreover, the diffusion of Cr into FePt grain surface area can decrease the crystal anisotropy constant of FePt. Therefore, Hc_{//} value is decreased as Cr or SiN_{y} content of the film is increased.

On the other hand, Cr is non-magnetic substance, increasing Cr content can dilute the Ms value of the magnetic film. When SiN_{y} volume fraction is fixed at 15 vol. %, the value of Ms for the annealed (Fe₅₀Pt₅₀)₈₅-(SiN_{y})₁₅ film (Cr=0 at. % is about 490 emu/cm³, but it can decrease to about 425 emu/cm³ as Cr content increases to 10 at. %, as shown in FIG. 8A. Owing to the reaction of pure FePtCr alloy film with Si substrate at high temperature, the value of Ms for the annealed (Fe₄₅Pt₄₅ Cr₁₀) alloy film ( SiN_{y}=0 vol. %) is only about 275 emu/cm³, but Ms can increase to about 480 emu/cm³ as SiN_{y} volume fraction of the film increases to 5 vol. %, as shown in FIG. 8B. This suggests the protective effect of SiN_{y} on the metal magnetic particles from reaction with Si substrate at high temperature is good. But, the Ms value decreases as SiN_{y} volume fraction higher than about 5 vol. %. Since SiN_{y} is also non-magnetic substance, it can dilute the Ms value of the magnetic film, the Ms value decreases from 480 emu/cm³ to about 180 emu/cm³ as SiN_{y} volume fraction is increased from 5 vol. % to 30 vol. %, as shown in FIG. 8B.

### EXAMPLE 4

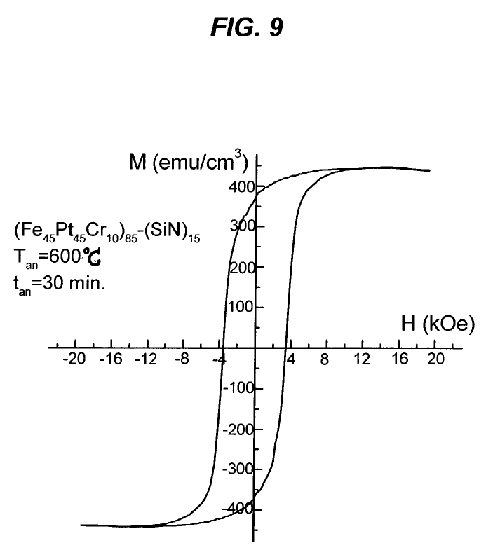

The sputtering conditions were the same as Example 1. FIG. 9. shows the M-H loop of the (Fe₄₅Pt₄₅Cr₁₀)₈₅-(SiN_{y})₁₅ thin film which was annealed at about 600° C. for about 30 minnutes. The applied field is parallel to the film plane. Its Ms value is measured to be about 425 emu/cm³ and Hc_{//} is about 3700 Oe.

Only a few embodiments are disclosed. However, it is understood that variations and enhancements may be made without departing from the spirit of and are intended to be encompassed by the following claims.

What is claimed is:

1. A method, comprising:
sputtering a magnetic material for forming magnetic grains, a grain-confining material to be present at boundaries of each magnetic grain, and a non-magnetic material for forming an amorphous matrix to disperse magnetic grains on a substrate, to form an initial soft magnetic granular film with small magnetic grains each bounded by the grain-confining material and dispersed in the amorphous matrix;
annealing the initial granular film in a vacuum under controlled annealing conditions at an annealing temperature over an annealing period; and
subsequently quenching the annealed film in a quenching liquid to complete transformation of the initial soft magnetic granular film into a hard magnetic granular film having a high in-plane magnetic coercivity and a high saturation magnetization.

2. The method as in claim 1, further comprising forming a passivation layer over the initial soft magnetic granular film prior to the annealing to prevent oxidation of the film during the annealing.

3. The method as in claim 2, wherein the passivation layer includes a film of silicon nitride.

4. The method as in claim 1, wherein the magnetic material includes FePt, and the grain-confining material includes Cr, and the non-magnetic material includes a silicon nitride.

5. The method as in claim 4, further comprising selecting each material for the film to cause the hard magnetic granular film to have a structure given by (Fe_{50-x/2}Pt_{50-x/2}Crₓ)_{100-δ}-(SiN_{y})_{δ} where x is between about 0 to about 30 at %, and δ is about 0 to about 30 vol. %.

6. The method of claim 4, further comprising selecting the atomic ratio of Fe:Pt:Cr in the film to be in a range from about 45:54:1 to about 41:34:25.

7. The method as in claim 6, wherein the atomic ratio of Fe:Pt:Cr in the film is about 45:45:10.

8. The method as in claim 4, wherein a volume fraction of FePtCr:SiN in the film is selected to be in a range from about 90:10 to about 50:50.

9. The method as in claim 8, wherein a volume fraction of FePtCr:SiN in the film is about 85:15.

10. The method as in claim 4, further comprising using a FePtCr target in the sputtering to supply FePt as the magnetic material and Cr as the grain-confining material.

11. The method as in claim 10, wherein the FePtCr target includes an FePtCr alloy target.

12. The method as in claim 10, wherein the FePtCr target includes a FePtCr composite target which comprises an FePt disk overlaid with Cr chips.

13. The method as in claim 1, wherein the substrate is a natural oxidized Si wafer or a glass substrate.

14. The method as in claim 1, further comprising using a magnetron sputtering system to perform the sputtering, wherein a DC or RF electric field is applied to produce plasma for the sputtering.

15. The method as in claim 1, further comprising setting an argon pressure in the sputtering between about 0.3 mTorr and about 20 mTorr.

16. The method as in claim 15, wherein the argon pressure is about 7 mTorr.

17. The method as in claim 1, further comprising setting a temperature of the substrate during the sputtering at a value less than about 45° C.

18. The method as in claim 17, wherein the substrate temperature is set to about 25° C. during the sputtering.

19. The method of claim 1, further comprising controlling a vacuum during the annealing to be at a pressure of lower than about 1×10⁻⁶ Torr.

20. The method as in claim 1, further comprising controlling the annealing temperature between about 400° C. and 800° C. for an annealing period between about 5 to 90 minutes.

21. The method as in claim 20, wherein the annealing temperature is set to about 600° C.

22. The method as in claim 20, wherein the annealing period is set to about 30 minutes.

23. The method as in claim 1, wherein the quenching liquid has a temperature of less than about 5° C.

24. The method as in claim 1, further comprising controlling material ratios and conditions for the annealing and quenching to cause an FePtCr-SiN granular film to have magnetic properties of Ms>425 emu/cm³ and Hc>3500 Oe, wherein FePt is the magnetic material, Cr is the grain-confining material, and SiN is the non-magnetic material.

25. A method, comprising:
forming a soft magnetic granular film on a substrate to have magnetic FePt grains dispersed in an amorphous silicon nitride matrix and to have Cr located at boundary of each FePt grain to confine the FePt;
annealing the film in a vacuum under controlled conditions for an annealing temperature and time period; and
quenching the film in a quenching liquid after annealing to transform the film into a hard magnetic film with a granular structure to exhibit a saturation magnetization of Ms >425 emu/cm³ and an in-plane magnetic coercivity of H_{c}>3500 Oe.

26. The method as in claim 25, wherein a sputtering process is used to sputter targets containing Fe, Pt, Cr, and a silicon nitride on the substrate in a controlled sputtering chamber.

27. The method as in claim 26, further comprising selecting the targets to produce an atomic ratio of Fe:Pt:Cr in the film to be in a range from about 45:54:1 to about 41:34:25.

28. The method as in claim 27, wherein the atomic ratio of Fe:Pt:Cr in the film is about 45:45:10.

29. The method as in claim 26, wherein a volume ratio between FePtCr and the silicon nitride in the film is selected to be in a range from about 90:10 to about 50:50.

30. The method as in claim 29, wherein a volume ratio between FePtCr and silicon nitride in the film is about 85:15.

31. The method as in claim 26, further comprising using a magnetron sputtering system to perform the sputtering, wherein a DC or RF electric field is applied to produce plasma for the sputtering.

32. The method as in claim 26, further comprising setting an argon pressure in the sputtering between about 0.3 mTorr and about 20 mTorr.

33. The method as in claim 26, further comprising setting a temperature of the substrate during the sputtering at a value less than about 45° C.

34. The method of claim 25, further comprising:
controlling a vacuum during the annealing to be at a pressure of lower than about 1×10⁻⁶ Torr; and
controlling the annealing temperature between about 400° C. and 800° C. for an annealing period between about 5 to 90 minutes.

35. The method as in claim 25, wherein the quenching liquid has a temperature of less than about 5° C.

36. The method as in claim 25, further comprising forming a passivation layer over the soft magnetic granular film prior to the annealing to prevent oxidation of the film during the annealing.
